(19) United States
(12) Patent Application Publication
(10) Pub. No.: US 2025/0017062 A1
(43) Pub. Date: Jan. 9, 2025

(54) DISPLAY DEVICE AND METHOD FOR FABRICATING THE SAME

(71) Applicant: Samsung Display Co., LTD., Yongin-si (KR)

(72) Inventors: Jung Suk BANG, Yongin-si (KR); Kwang Su PARK, Yongin-si (KR); Tae Ung PARK, Yongin-si (KR); Taek Gyun LEE, Yongin-si (KR)

(21) Appl. No.: 18/604,391

(22) Filed: Mar. 13, 2024

(30) Foreign Application Priority Data
Jul. 4, 2023 (KR) 10-2023-0086217

(51) Int. Cl. H10K 59/131; H10K 59/12

(52) U.S. Cl. CPC H10K 59/131; H10K 59/1201

(57) ABSTRACT

A display device includes: a substrate comprising a first display area and a second display area around the first display area; pixels on the substrate and comprising respective pixel transistors in the first display area, and respective light-emitting elements in the first display area and the second display area and connected to the respective pixel transistors; and connection lines connecting the pixel transistors with the light-emitting elements, respectively, wherein each of the connection lines comprises one or more straight portions extending in a first direction, and one or more oblique portions connected to the straight portions and extending in an oblique direction inclined by an angle equal to a multiple of 45° with respect to the first direction, and wherein angles formed by the straight portions and the oblique portions of the connection lines are equal to each other.

### CROSS-REFERENCE TO RELATED APPLICATION

The present application claims priority to and the benefit of Korean Patent Application No. 10-2023-0086217, filed on Jul. 4, 2023, in the Korean Intellectual Property Office, the entire disclosure of which is incorporated herein by reference.

### BACKGROUND

### 1. Field

Aspects of some embodiments of the present disclosure relate to a display device, and a method of fabricating the same.

### 2. Description of the Related Art

Display devices have become more and more important as multimedia technology evolves. Accordingly, a variety of display devices such as liquid-crystal display devices and organic light-emitting display devices are currently being developed.

A display device may include a display area where pixels are arranged and images are displayed, and a non-display area outside the display area. Recently, a display device capable of expanding the display area by reducing the non-display area is in demand.

The above information disclosed in this Background section is only for enhancement of understanding of the background and therefore the information discussed in this Background section does not necessarily constitute prior art.

### SUMMARY

Aspects of some embodiments of the present disclosure include a display device in which a display area is expanded by reducing a non-display area and connection lines for connecting pixel driving units with emission units of pixels are arranged uniformly.

However, aspects of embodiments according to the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, there is provided a display device including a substrate including a first display area and a second display area around the first display area, pixels on the substrate and including respective pixel transistors in the first display area, and respective light-emitting elements in the first display area and the second display area and connected to the respective pixel transistors, and connection lines connecting the pixel transistors with the light-emitting elements, respectively, wherein each of the connection lines includes one or more straight portions extended in a first direction, and one or more oblique portions connected to the straight portions and extended in an oblique direction inclined by an angle equal to a multiple of 45° with respect to the first direction, and wherein angles formed by the straight portions and the oblique portions of the connection lines are equal to each other.

According to some embodiments, the angles formed by the straight portion and the oblique portion of each of the connection lines may be equal to 135°.

According to some embodiments, each of the connection lines may have a width of a first length.

According to some embodiments, straight portions of two adjacent ones of the connection lines may be spaced apart from each other by a spacing equal to the first length.

According to some embodiments, the pixels may further include connection electrodes connected to the respective pixel transistors, first connection portions overlapping the connection electrodes, and second connection portions overlapping first electrodes of the light-emitting elements, and each of the connection lines may be connected between a first connection portion and a second connection portion of one of the pixels.

According to some embodiments, the connection lines may include a first connection line including a single straight portion and a single oblique portion, and a second connection line adjacent to the first connection line and including at least two straight portions and at least two oblique portions.

According to some embodiments, the first connection portion connected to the first connection line and the first connection portion connected to the second connection line may be arranged in parallel in the first direction, and the second connection portion connected to the first connection line and the second connection portion connected to the second connection line may be arranged in parallel in the first direction.

According to some embodiments, each of the straight portions of the second connection line may be parallel to the straight portion of the first connection line in the first direction or in a second direction orthogonal to the first direction.

According to some embodiments, the display device may further include a dummy pattern in a space between the connection lines and including a straight pattern parallel to the straight portions of the connection lines and an oblique pattern parallel to the oblique portions of the connection lines.

According to some embodiments, the connection lines and the dummy pattern may be arranged at a uniform spacing in a display area including the first display area and the second display area.

According to some embodiments, the dummy pattern may be in a same layer and include a same material as the connection lines.

According to some embodiments, the display device may further include a circuit layer on the substrate and including the pixel transistors, and a light-emitting element layer overlapping the circuit layer and including the light-emitting elements.

According to some embodiments, the display device may further include an embedded driver circuit in the circuit layer and including a driver transistor in the second display area.

According to some embodiments, the embedded driver circuit may overlap the light-emitting element of at least one of the pixels.

According to some embodiments, a first pixel among the pixels may include a first pixel transistor in the first display area and a first light-emitting element in the second display area, and a second pixel among the pixels may include a second pixel transistor in the first display area and a second light-emitting element in the first display area.

According to some embodiments, a connection line connecting the first pixel transistor with the first light-emitting element may have a greater length than a connection line connecting the second pixel transistor with the second light-emitting element.

According to some embodiments, each of the pixels may include a pixel driving unit including at least one pixel transistor and an emission unit including at least one light-emitting element, and among the pixels, at least two pixels having respective pixel driving units adjacent to each other and respective light-emitting units adjacent to each other may form a unit pixel.

According to some embodiments, pixel driving units and light-emitting units of unit pixels formed by the pixels may be arranged in the first display area and the second display area, the pixel driving units of the unit pixels may be arranged in the first display area at a first pitch in the first direction, and the emission units of the unit pixels may be arranged in the first display area and the second display area at a second pitch greater than the first pitch in the first direction.

According to some embodiments, the straight portion and the oblique portion of each of the connection lines may be formed as a single piece.

According to some embodiments of the present disclosure, there is provided a method of fabricating a display device including pixels, wherein the pixels include pixel transistors, light-emitting elements and connection lines connecting the pixel transistors with the light-emitting elements, the method including inputting locations of first connection portions connected to the pixel transistors and locations of second connection portions connected to the light-emitting elements into a design program, inputting line path search conditions for the connection lines, sequentially searching for line paths for the connection lines under the line path search conditions, and forming the connection lines between the first connection portions and the second connection portions according to the found line paths, wherein the line path search conditions include a condition that each square in a grid of squares having four sides with a length equal to a multiple of a width of each of the connection lines is a minimum movement unit, and a condition that a path moves only in straight line directions in which the sides of the grid are extended and in diagonal directions of the grid.

According to some embodiments, both a first display area where pixel driving units are located and a second display area around the first display area (e.g., the area where an embedded driving circuit is located) can be utilized as a display area. Accordingly, a non-display area of the display device can be relatively reduced while the display area can be expanded.

In addition, according to some embodiments, connection lines can be arranged at a regular spacing, and the lengths of the connection lines can be relatively shortened. Accordingly, it may be possible to uniformly form the connection lines and to reduce or minimize voltage drop and voltage drop deviations in the connection lines.

However, characteristics according to the embodiments of the present disclosure are not limited to those described above and various other characteristics are incorporated herein.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is a plan view showing a display device according to some embodiments of the present disclosure.

FIG. 2 is a cross-sectional view showing a structure of the display device according to some embodiments of the present disclosure.

FIG. 3 is a circuit diagram showing a pixel according to some embodiments of the present disclosure.

FIG. 4 is a circuit diagram showing a pixel according to some embodiments of the present disclosure.

FIG. 5 is a plan view showing a display area according to some embodiments of the present disclosure.

FIG. 6 is a cross-sectional view showing a display device according to some embodiments of the present disclosure.

FIG. 7 is a plan view showing first connection portions and second connection portions according to some embodiments of the present disclosure.

FIG. 8 is a plan view showing connection lines according to some embodiments of the present disclosure.

FIG. 9 is a plan view showing parts of connection lines according to some embodiments of the present disclosure.

FIG. 10 is a flowchart for illustrating a method of forming connection lines according to some embodiments of the present disclosure.

FIG. 11 is a plan view showing found line paths according to some embodiments of the present disclosure.

FIG. 12 is a plan view showing connection lines and dummy patterns according to some embodiments of the present disclosure.

FIG. 13 is a plan view partially showing connection lines and dummy patterns according to some embodiments of the present disclosure.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will more fully convey the scope of embodiments according to the present invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, aspects of some embodiments of the present disclosure will be described in more detail with reference to the accompanying drawings.

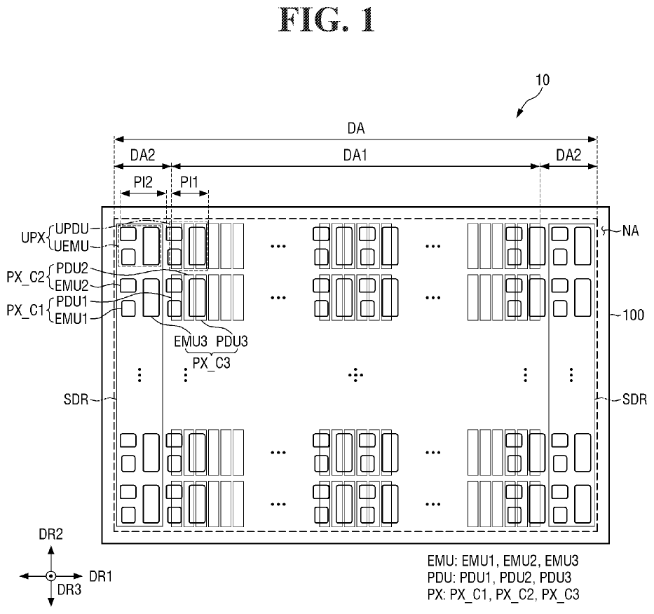

FIG. 1 is a plan view showing a display device 10 according to some embodiments of the present disclosure. In FIG. 1, the structure of the display device 10 is shown schematically, focusing on a display panel including a display area DA.

Referring to FIG. 1, the display device 10 may include a substrate 100 (or a base member), and pixels PX and an embedded driver circuit SDR located on the substrate 100. The pixels PX and the embedded driver circuit SDR (or a part of the embedded driver circuit SDR) may be located in the display area DA.

The display device 10 may be implemented in a variety of shapes. According to some embodiments of the present disclosure, the display device 10 may be implemented as a rectangular panel as shown in FIG. 1. Although the display device 10 includes sharp corners in the example shown in FIG. 1, the display device 10 may include rounded corners.

The display device 10 may have a variety of shapes according to some embodiments. For example, the display device 10 may be implemented in a non-rectangular shape. For example, the display device 10 may be implemented in a polygonal shape (e.g., a hexagonal shape) other than a rectangular shape, a circular shape, or an elliptical shape.

The display device 10 may be implemented as a substantially flat 2D panel or as a 3D panel having curves in the thickness direction or the like. The display device 10 may be a rigid display device that is not substantially deformed, or a flexible display device that can be deformed, i.e., at least partially folded, bent or rolled.

For convenience of illustration, the display device 10 has a rectangular flat plane shape in the example shown in FIG. 1. The horizontal direction (e.g., the row direction or the X direction) of the display device 10 is referred to as a first direction DR1, the vertical direction (e.g., the column direction or the Y direction) of the display device 10 is referred to as a second direction DR2, and the thickness direction (e.g., the height direction or the Z direction) of the display device 10 is referred to as a third direction DR3.

The substrate 100 is a base member for fabricating or providing the display device 10 and may form, for example, a base surface of the display device 10. The substrate 100 may include a display area DA in which the pixels PX are located, and a non-display area NA excluding the display area DA. In the display area DA, images may be displayed by the pixels PX. The non-display area NA may be the area other than the display area DA (e.g., in a periphery or outside a footprint of the display area DA).

The display area DA may include a first display area DA1 and a second display area DA2. The second display area DA2 may be located on at least one side of the first display area DA1 and may be closer to the edge of the display device 10 than the first display area DA1. According to some embodiments, the second display area DA2 where the embedded driver circuit SDR (or a part of the embedded driver circuit SDR) is located may be located on each of the both sides of the first display area DA1 in the first direction DR1.

The display device 10 may include pixels PX emitting lights of different colors. For example, the display device 10 may include first color pixels PX_C1 emitting lights of a first color (e.g., red light having a wavelength range of approximately 610 nm to 680 nm and a peak wavelength in the range of 610 nm to 650 nm), second color pixels PX_C2 emitting lights of a second color (e.g., green light having a wavelength range of approximately 500 nm to 570 nm and a peak wavelength in the range of 510 nm to 550 nm), and third color pixels PX_C3 emitting lights of a third color (e.g., blue light having a wavelength range of approximately 430 nm to 500 nm and a peak wavelength in the range of 440 nm to 480 nm). The colors of lights emitted from the different pixels PX may vary depending on embodiments.

At least one first color pixel PX_C1, at least one second color pixel PX_C2 and at least one third color pixel PX_C3 which are located adjacent to one another, (for example, their emission units EMU are located adjacent to one another and their pixel driving units PDU are located adjacent to one another) may be form a single unit pixel UPX. For example, each unit pixel UPX may include one first color pixel PX_C1, one second color pixel PX_C2 and one third color pixel PX_C3. The type, number and/or ratio of the pixels PX forming a unit pixel UPX may vary depending on embodiments. By individually controlling the emission luminance of the first, second and third color pixels PX_C1, PX_C2 and PX_C3 forming each unit pixel UPX, lights of a variety of colors can be emitted from the unit pixel UPX.

Each pixel PX may include an emission unit EMU including at least one light-emitting element, and a pixel driving unit PDU (e.g., a pixel circuit) electrically connected to the emission unit EMU. For example, each first color pixel PX_C1 may include a first emission unit EMU1 including at least one light-emitting element and emitting light of the first color, and a first pixel driving unit PDU1 electrically connected to the first emission unit EMU1. Each second color pixel PX_C2 may include a second emission unit EMU2 including at least one light-emitting element and emitting light of the second color, and a second pixel driving unit PDU2 electrically connected to the second emission unit EMU2. Each third color pixel PX_C3 may include a third emission unit EMU3 including at least one light-emitting element and emitting light of the third color, and a third pixel driving unit PDU3 electrically connected to the third emission unit EMU3.

The emission units EMU of the pixels PX may have substantially the same size or different sizes. For example, the first emission unit EMU1 of the first color pixel PX_C1 may have the same area as or a different area from the second emission unit EMU2 of the second color pixel PX_C2 and/or the third emission unit EMU3 of the third color pixel PX_C3. The size, shape and/or ratio of the emission units EMU of the pixels PX may vary depending on different embodiments. In addition, the arrangement direction and/or arrangement structure of the pixels PX may vary in various embodiments. For example, the arrangement direction and/or arrangement structure of the emission units EMU of the pixels PX may vary depending on different embodiments. Similarly, the arrangement direction and/or arrangement structure of the pixel driving units PDU of the pixels PX may vary depending on different embodiments.

The emission units EMU of the pixels PX may be located in the display area DA including the first display area DA1 and the second display area DA2. The pixel driving units PDU of the pixels PX may be located only in the first display area DA1 but may not be located in the second display area DA2. The embedded driver circuit SDR may be located in the second display area DA2. The embedded driver circuit SDR may overlap at least some of the emission units EMU of the pixels PX located in the second display area DA2.

As the emission units EMU of the pixels PX are located in a larger area (e.g., the display area DA including the first display area DA1 and the second display area DA2) than the area where the pixel driving units PDU are located (e.g., the first display area DA1), the emission units EMU of the pixels PX may be arranged at a larger pitch than the pixel driving units PDU. For example, pixel driving units UPDU and emission units UEMU of unit pixels UPX each including at least one first color pixel PX_C1, at least one second color pixel PX_C2 and at least one third color pixel PX_C3 may be arranged in the display area DA along at least the first direction DR1 (e.g., the first and second directions DR1 and DR2). The pixel driving units UPDU of the unit pixels UPX may be arranged in the first display area DA1 at a first pitch PI1 in the first direction DR1. The emission units UEMU of the unit pixels UPX may be arranged in the first display area DA1 and the second display area DA2 at a second pitch PI2 greater than the first pitch PI1 in the first direction DR1. At least some of the emission units EMU of the pixels PX located in the second display area DA2 may overlap the embedded driver circuit SDR. Accordingly, by using the area where the embedded driver circuit SDR is located as the display area DA, the non-display area NA can be reduced and the display area DA can be expanded.

The display device 10 may further include a driver circuit for driving the pixels PX (e.g., a scan driver circuit, a data driver circuit, and a timing controller). According to some embodiments of the present disclosure, a part of the driver circuit may be implemented as the embedded driver circuit SDR formed and/or located inside the display panel, while another part of the driver circuit may be located in the non-display area NA of the display panel and/or mounted on a circuit board electrically connected to the display panel.

The embedded driver circuit SDR may be located in the second non-display area DA2. The embedded driver circuit SDR may be located on at least one side of the first display area DA1. For example, the embedded driver circuit SDR may be located on one side (e.g., left or right) of the first display area DA1 or on the both sides (e.g., left and right) of the first display area DA1.

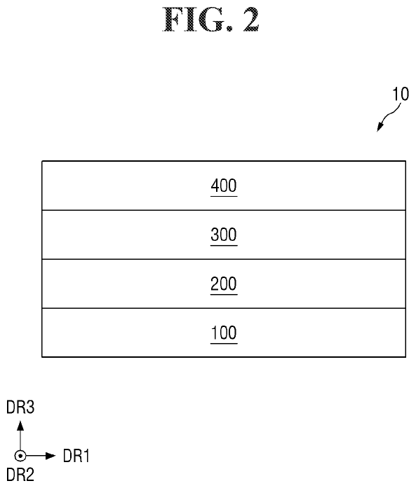

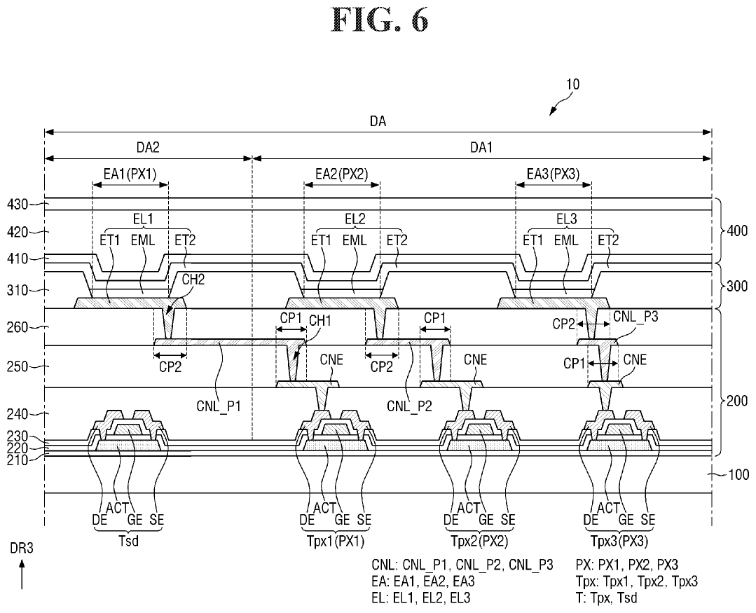

The embedded driver circuit SDR may be located and/or formed in the display panel together with the pixels PX. For example, the embedded driver circuit SDR may include circuit elements (e.g., driver transistors and capacitors) located in a circuit layer (e.g., a circuit layer 200 of FIGS. 2 and 6) of the display device 10 together with the pixel driving units PDU of the pixels PX. According to some embodiments of the present disclosure, circuit elements of the embedded driver circuit SDR (or some of the circuit elements) and lines connected thereto may be formed together with the circuit elements forming the pixel driving units PDU of the pixels PX.

According to some embodiments of the present disclosure, the embedded driver circuit SDR may include a gate driver circuit such as a scan driver circuit or a part of the gate driver circuit. The gate driver circuit may be connected to the pixels PX through scan lines and the like, and may supply respective gate signals (e.g., respective scan signals) to the pixels PX.

The non-display area NA may be arranged around (e.g., in a periphery or outside a footprint of) the display area DA. The lines and/or pads connected to the pixels PX and/or the embedded driver circuit SDR of the display area DA may be located in the non-display area NA.

FIG. 2 is a cross-sectional view showing a structure of the display device 10 according to some embodiments of the present disclosure.

Referring to FIGS. 1 and 2, the display device 10 may include the substrate 100, and the circuit layer 200, a light-emitting element layer 300 and an encapsulation layer 400 sequentially arranged on the substrate 100. It should be understood, however, that the structure of the display device 10 is not limited thereto. For example, the circuit layer 200 and the light-emitting element layer 300 may overlap each other, and the order in which the circuit layer 200 and the light-emitting element layer 300 are located may be changed. The encapsulation layer 400 may be located or formed to encapsulate at least the light-emitting element layer 300.

The substrate 100 may be a rigid or flexible substrate and may have a single-layer or multi-layer structure. According to some embodiments of the present disclosure, the substrate 100 may be, but is not limited to, one of a glass substrate, a quartz substrate, a glass ceramic substrate, a film substrate including a polymeric organic material, and a plastic substrate.

The circuit layer 200 (also referred to as a panel circuit layer or a backplane layer) may include circuit elements and lines located inside the display panel. For example, the circuit layer 200 may include circuit elements located in the first display area DA1 and forming the pixel driving unit PDU of each of the pixels PX (e.g., pixel transistors and capacitors), circuit elements located in the second display area DA2 and forming the embedded driver circuit SDR (e.g., driving unit transistors and capacitors), and lines connected to the pixels PX and/or the embedded driver circuit SDR. In the following description of the embodiments, the term “connection” may encompass electrical and/or physical connection.

The light-emitting element layer 300 (also referred to as a light source unit or light-emitting element unit) may include light-emitting elements working as light sources for the pixels PX. For example, the light-emitting element layer 300 may include self-light-emitting elements located or formed in emission areas of the pixels PX. For example, each of the pixels PX may include an organic light-emitting diode, a quantum-dot light-emitting diode, an inorganic-based micro light-emitting diode (e.g., micro LED), an inorganic-based nano light-emitting diode (e.g., nano LED), or other types of self-light-emitting elements.

The encapsulation layer 400 may be located on the light-emitting element layer 300. For example, the encapsulation layer 400 may be located on the light-emitting element layer 300 to encapsulate the display area DA in which the light-emitting elements of the pixels PX are located.

According to some embodiments of the present disclosure, the display device 10 may further include additional elements. For example, the display device 10 may further include at least one of a touch sensor layer, a color filter layer, a polarization layer, or a protective layer. Each of the touch sensor layer, the color filter layer, the polarization layer and the protective layer may be formed or located directly on the surface of the substrate 100 where the pixels PX are located, or may be formed from the display panel including the pixels PX and then may be attached to the display panel.

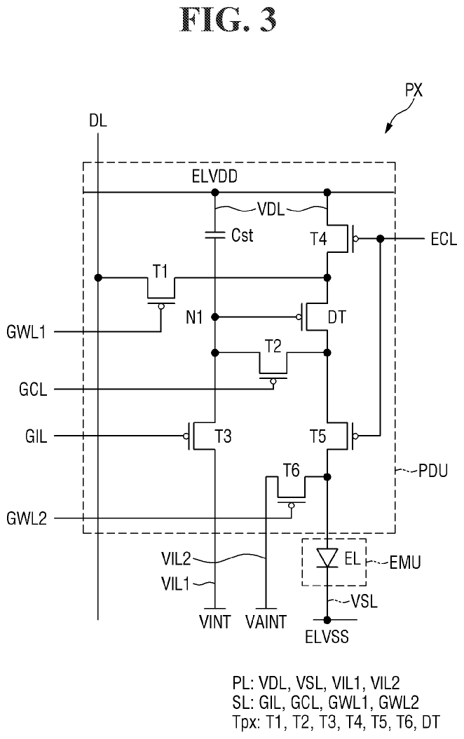

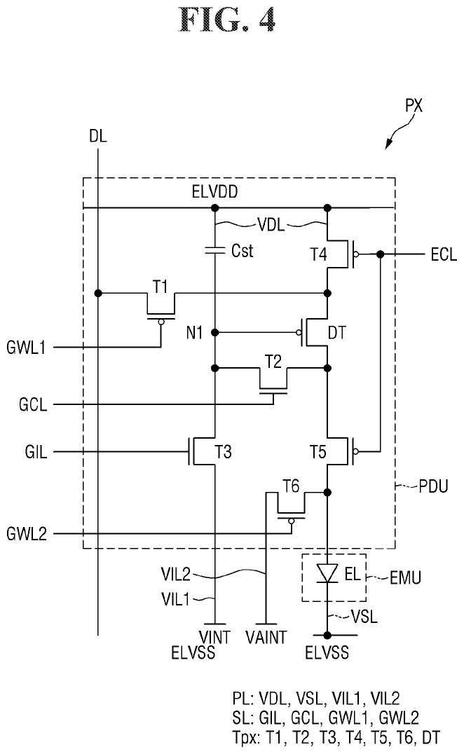

FIG. 3 is a circuit diagram showing a pixel PX according to some embodiments of the present disclosure. FIG. 4 is a circuit diagram showing a pixel PX according to some embodiments of the present disclosure. For example, FIGS. 3 and 4 show different embodiments with respect to the type of pixel transistors Tpx.

In the examples shown in FIGS. 3 and 4, scan lines SL connected to the pixels PX include a scan initialization line GIL, a scan control line GCL, a first scan line GWL1 and a second scan line GWL2. In addition, in the embodiments shown in FIGS. 3 and 4, the power lines PL connected to the pixels PX include a first supply voltage line VDL, a second supply voltage line VSL, a first initialization voltage line VIL1 and a second initialization voltage line VIL2. The type and number of the scan lines SL and the power lines PL connected to each pixel PX may vary depending on the structure of the pixel PX.

Referring to FIGS. 3 and 4 in conjunction with FIGS. 1 and 2, the pixel PX may include an emission unit EMU including at least one light-emitting element EL, and a pixel driving unit PDU connected to the emission unit EMU.

The light-emitting element EL may be connected between a second supply voltage line VSL from which a second supply voltage ELVSS is applied and the pixel driving unit PDU. The light-emitting element EL is the light source of the pixel PX and may emit light in response to a driving current supplied from the pixel driving unit PDU. As the driving current increases, the light-emitting element EL may emit light with higher luminance.

The light-emitting element EL may be, but is not limited to, an organic light-emitting diode. For example, the light-emitting element EL may be an inorganic light-emitting element, a quantum-dot light-emitting element, or other types of light-emitting element.

The pixel driving unit PDU may control the emission timing and luminance of the light-emitting element EL by controlling the driving current supplied to the light-emitting element EL. The pixel driving unit PDU may include at least one pixel transistor Tpx and a capacitor Cst. According to some embodiments of the present disclosure, the pixel driving unit PDU may include a driving transistor DT and pixel transistors Tpx including switch elements. The switch elements may include first to sixth transistors T1, T2, T3, T4, T5 and T6.

The driving transistor DT may include a gate electrode connected to a first node N1, a first electrode connected to the first supply voltage line VDL via the fourth transistor T4, and a second electrode connected to the emission unit EMU via the fifth transistor T5. One of the first electrode and the second electrode may be a source electrode, and the other may be a drain electrode. The driving transistor DT may control a source-drain current (hereinafter referred to as a driving current) flowing between the first electrode and the second electrode in response to the voltage applied to the gate electrode (e.g., the voltage of the first node N1 corresponding to the voltage of the data signal).

The first transistor T1 may include a gate electrode connected to a first scan line GWL1, a first electrode connected to a data line DL, and a second electrode connected to the first electrode of the driving transistor DT. The first transistor T1 may be turned on by the first scan signal supplied to the first scan line GWL1 to connect the first electrode of the driving transistor DT with the data line DL. When the first transistor T1 is turned on, the voltage of the data signal supplied to the data line DL may be applied to the first electrode of the driving transistor DT.

The second transistor T2 may include a gate electrode connected to the scan control line GCL, a first electrode connected to the second electrode of the driving transistor DT, and a second electrode connected to the gate electrode of the driving transistor DT (or the first node N1). The second transistor T2 may be turned on by a scan control signal supplied to the scan control line GCL to connect the gate electrode of the driving transistor DT with the second electrode. When the second transistor T2 is turned on, the driving transistor DT may work like a diode.

The third transistor T3 may include a gate electrode connected to the scan initialization line GIL, a first electrode connected to the gate electrode of the driving transistor DT, and a second electrode connected to the first initialization voltage line VIL1. The third transistor T3 may be turned on by a scan initialization signal supplied to the scan initialization line GIL to connect the gate electrode of the driving transistor DT with the first initialization voltage line VIL1. When the third transistor T3 is turned on, the first initialization voltage VINT of the first initialization voltage line VIL1 may be applied to the gate electrode of the driving transistor DT.

The fourth transistor T4 may include a gate electrode connected to an emission control line ECL, a first electrode connected to the first supply voltage line VDL, and a second electrode connected to the first electrode of the driving transistor DT. The fourth transistor T4 may be turned on by an emission control signal supplied to the emission control line ECL to connect the first electrode of the driving transistor DT with the first supply voltage line VSL from which the first supply voltage ELVDD is applied. When the fourth transistor T4 is turned on, the first supply voltage ELVDD may be applied to the first electrode of the driving transistor DT.

The fifth transistor T5 may include a gate electrode connected to the emission control line ECL, a first electrode connected to the second electrode of the driving transistor DT, and a second electrode connected to the light-emitting element EL. The fifth transistor T5 may be turned on by the emission control signal supplied to the emission control line ECL to connect the driving transistor DT with the light-emitting element EL. When both the fourth transistor T4 and the fifth transistor T5 are turned on, the driving current corresponding to the voltage of the gate electrode of the driving transistor DT may flow through the light-emitting element EL.

The sixth transistor T6 may include a gate electrode connected to the second scan line GWL2, a first electrode connected to an anode electrode of the light-emitting element EL, and a second electrode connected to the second initialization voltage line VIL2. The sixth transistor T6 may be turned on by a second scan signal supplied to the second scan line GWL2 to connect the anode electrode of the light-emitting element EL with the second initialization voltage line VIL2. The second scan signal may be either identical to or different from the first scan signal. When the sixth transistor T6 is turned on, a second initialization voltage VAINT of the second initialization voltage line VIL2 may be applied to the anode electrode of the light-emitting element EL.

The capacitor Cst may be connected between the gate electrode of the driving transistor DT and the first supply voltage line VDL. The capacitor Cst may store a voltage corresponding to the voltage of the data signal applied to the gate electrode of the driving transistor DT.

According to some embodiments of the present disclosure, an active layer (e.g., a semiconductor pattern including a channel region) of each of the pixel transistors Tpx (e.g., the driving transistor DT and the first to sixth transistors T1, T2, T3, T4, T5 and T6) may be formed of one of polysilicon, amorphous silicon, and oxide semiconductor. For example, as in the embodiments of FIG. 3, all of the pixel transistors Tpx may be implemented as p-type transistors (e.g., p-type MOSFETs). The active layer of each of the pixel transistors Tpx may be formed of polysilicon or an oxide semiconductor.

Alternatively, as in the embodiments of FIG. 4, some of the pixel transistors Tpx, e.g., the driving transistor DT and the first, fourth, fifth and sixth transistors T1, T4, T5 and T6 may be implemented as p-type transistors, and some others of the pixel transistors Tpx, e.g., the second transistor T2 and the third transistor T3 may be implemented as n-type transistors (e.g., n-type MOSFETs). According to some embodiments of the present disclosure, the active layer of each of the driving transistor DT and the first, fourth, fifth and sixth transistors T1, T4, T5 and T6 implemented as p-type transistors may be formed of polysilicon, and the active layer of each of the second and third transistors T2 and T3 implemented as n-type transistors may be formed of oxide semiconductor. According to some embodiments of the present disclosure, transistors including the active layers formed of polysilicon and transistors including the active layers formed of oxide semiconductor may be located in different layers on the substrate 100.

The structure of the pixel PX may vary according to some embodiments. For example, according to some embodiments, the pixel PX may include additional components or fewer components without departing from the spirit and scope of embodiments according to the present disclosure.

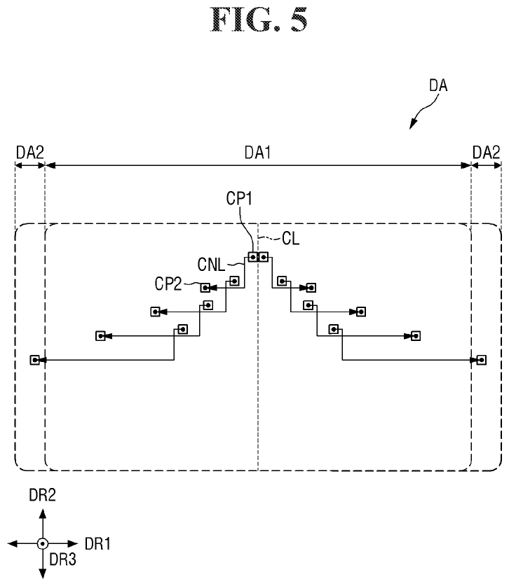

FIG. 5 is a plan view showing a display area DA according to some embodiments of the present disclosure. In FIG. 1, the structure of the display device 10 is shown schematically, focusing on a display panel including a display area DA.

Referring to FIGS. 1 to 5, the pixel driving units PDU of the pixels PX may be located in the first display area DA1, and the emission units EMU of the pixels PX may be located in the first display area DA1 and the second display area DA2. The emission units EMU of the pixels PX may be located at shifted positions in the first direction DR1 and/or the second direction DR2 relative to the pixel driving units PDU. For example, the emission units EMU of the pixels PX may be located at shifted positions in both directions relative to the pixel driving units PDU from the center of the display area DA at least in the first direction DR1 (e.g., an area including a virtual center line CL indicated by the dashed line in FIG. 4). For example, the emission units EMU of the pixels PX may be located at shifted positions in both directions (e.g., left direction or right direction) in the first direction DR1 relative to the emission units EMU in the directions of the arrows indicated at the ends of the connection lines CNL in FIG. 5.

The emission units EMU of the pixels PX may be connected to respective pixel driving units PDU through respective connection lines CNL. The connection lines CNL may be connected to the respective pixel driving units PDU at first connection portions CP1 (or first contact pads formed on the first connection portions CP1), and may be connected to the respective emission units EMU at second connection portions CP2 (or second contact pads formed on the second connection portions CP2). For example, on end of each of the connection lines CNL may be positioned at the first connection portions CP1 of the respective pixel PX, and may be electrically connected to at least one pixel transistor Tpx included in the pixel driving unit PDU of the respective pixel PX at the first connection portion CP1. The other end of each of the connection lines CNL may be positioned at the second connection portions CP2 of the respective pixel PX, and may be electrically connected to the light-emitting element EL included in the emission unit EMU of the respective pixel PX at the second connection portion CP2. The connection lines CNL may also be regarded as elements included in the respective pixels PX.

Each of the first connection portions CP1 may be located in an area where the pixel driving unit PDU of the pixel PX is located or a connection electrode (e.g., the connection electrode CNE of FIG. 6) connected to the pixel driving unit PDU is located. Each of the second connection portions CP2 may be located in an area where the emission unit EMU of the pixel PX is located or an electrode of the light-emitting element EL (e.g., the first electrode ET1 of FIG. 6) located in the emission unit EMU or a bridge pattern connected to the electrode of the light-emitting element EL is located.

According to some embodiments of the present disclosure, the second connection portion CP2 formed in one pixel PX may be located farther from the center of the display area DA in at least the first direction DR1 than the first connection portion CP1 formed in the respective pixel PX. According to some embodiments of the present disclosure, the second connection portions CP2 may be located at shifted positions in the first direction DR1 and the second direction DR2 relative to the first connection portions CP1 associated with them, but embodiments according to the present disclosure are not limited thereto. For example, the positions of the first connection portions CP1 and the second connection portions CP2 may be variously changed depending on the design structure of the pixels PX.

FIG. 6 is a cross-sectional view showing a display device 10 according to some embodiments of the present disclosure. For example, FIG. 6 shows a cross section of a part of the display area DA in which the pixel transistors Tpx and light-emitting elements EL of the first pixel PX1, the second pixel PX2 and the third pixel PX3 are located. Each of the first pixel PX1, the second pixel PX2 and the third pixel PX3 may be a first color pixel PX_C1, a second color pixel PX_C2 or a third color pixel PX_C3.

Referring to FIGS. 1 to 6, the display device 10 may include the substrate 100, and the circuit layer 200, the light-emitting element layer 300 and the encapsulation layer 400 sequentially located on the substrate 100. The circuit layer 200, the light-emitting element layer 300 and the encapsulation layer 400 may overlap with one another and may be sequentially arranged or stacked in the third direction DR3.

The circuit layer 200 may include circuit elements forming the pixel driving units PDU, circuit elements forming the embedded driver circuit SDR, and lines. FIG. 6 shows, among the elements located in the circuit layer 200, pixel transistors Tpx located in the pixel driving units PDU of the first pixel PX1, second pixel PX2 and third pixel PX3 and connected to the light-emitting elements EL of the pixels PX, and one driver transistor Tsd among the circuit elements located in the embedded driver circuit SDR. For example, FIG. 6 shows, among the elements located in the circuit layer 200, one pixel transistor Tpx (hereinafter referred to as first pixel transistor Tpx1) connected to the light-emitting element EL (hereinafter referred to as first light-emitting element EL1) of the first pixel PX1; one pixel transistor Tpx (hereinafter referred to as second pixel transistor Tpx2) connected to the light-emitting element EL (hereinafter referred to as second light-emitting element EL2) of the second pixel PX2; one pixel transistor Tpx (hereinafter referred to as third pixel transistor Tpx3) connected to the light-emitting element EL (hereinafter referred to as third light-emitting element EL3) of the third pixel PX3; and one driver transistor Tsd located in the embedded driver circuit SDR.

The pixel transistors Tpx may be located in the first display area DA1 in the circuit layer 200, and the driver transistor Tsd may be located in the second display area DA2 in the circuit layer 200. Each of the transistors T, e.g., each of the pixel transistors Tpx and each of the driver transistors Tsd may include an active layer ACT, a gate electrode GE, a source electrode SE, and a drain electrode DE.

The circuit layer 200 may include at least one semiconductor layer, conductive layers, and insulating layers for forming the circuit elements and the lines. For example, the circuit layer 200 may include a first insulating layer 210 (e.g., a buffer layer), a semiconductor layer, a second insulating layer 220 (e.g., a gate insulator), a first conductive layer (e.g., a gate conductive layer), a third insulating layer 230 (e.g., an interlayer dielectric layer), a second conductive layer (e.g., a first source-drain conductive layer), a fourth insulating layer 240 (e.g., a first via layer or a first planarization layer), a third conductive layer (e.g., a second source-drain conductive layer), a fifth insulating layer 250 (e.g., a second via layer or a second planarization layer), a fourth conductive layer (e.g., an intermediate conductive layer or a connection conductive layer), and a sixth insulating layer 260 (e.g., a third via layer or a third planarization layer), which are sequentially located on the substrate 100 in the third direction DR3.

Although the fourth conductive layer and the sixth insulating layer 260 are included in the circuit layer 200 in the example shown in FIG. 6, the embodiments according to the present disclosure are not limited thereto. For example, the fourth conductive layer and the sixth insulating layer 260 may be included in the light-emitting element layer 300 or may be included in an intermediate layer located between the circuit layer 200 and the light-emitting element layer 300.

The first insulating layer 210 may include at least one inorganic film including an inorganic insulating material (e.g., silicon nitride, silicon oxide, silicon oxynitride, titanium oxide, aluminum oxide, or other inorganic insulating materials). It should be understood, however, that embodiments according to the present disclosure are not limited thereto. The material of the first insulating layer 210 may be changed.

According to some embodiments of the present disclosure, an additional conductive layer may be located between the substrate 100 and the first insulating layer 210. For example, between the substrate 100 and the first insulating layer 210a bottom metal layer BML overlapping the active layer ACT of the at least one transistor T and/or a conductive layer (e.g., a lower conductive layer) including at least one line (or a part of the at least one line) may be located.

The semiconductor layer may include the active layer ACT of each of the transistors T. The semiconductor layer may include polycrystalline silicon, single crystal silicon, low-temperature polycrystalline silicon, amorphous silicon, or an oxide semiconductor. The active layer ACT may include a channel region, a source region and a drain region.

The second insulating layer 220 may include at least one inorganic film including an inorganic insulating material (e.g., the inorganic insulating materials listed above as the material for the first insulating layer 210 or other inorganic insulating materials). The material for the second insulating layer 220 may be changed according to some embodiments.

The first conductive layer may include a gate electrode GE of each of the transistors T. Each gate electrode GE may include a conductive material (e.g., at least one of molybdenum (Mo), aluminum (Al), chromium (Cr), gold (Au), titanium (Ti), nickel (Ni), neodymium (Nd), copper (Cu), and/or other metals, alloys thereof, or other conductive materials), and may be a single-layer or multi-layered electrode. The first conductive layer may further include at least one line including a conductive material (or a part of the at least one line), a bridge pattern, and/or a capacitor electrode.

The third insulating layer 230 may include at least one inorganic film including an inorganic insulating material (e.g., the inorganic insulating materials listed above as the material for the first insulating layer 210 or other inorganic insulating materials). The material for the third insulating layer 230 may be changed according to some embodiments.

The second conductive layer may include the source electrode SE and the drain electrode DE of each of the transistors T. The source electrode SE and the drain electrode DE may include a conductive material and may be a single-layer or multi-layer electrode. According to some embodiments, the source electrode SE and the drain electrode DE of each of the transistors T may be formed integrally with the source and drain regions of the active layer ACT. The third conductive layer may include a bridge pattern connected to the source electrode SE or the drain electrode DE of the at least one transistor T.

In order to provide a flat surface in the circuit layer 200, the fourth insulating layer 240 may include at least one organic film including an organic insulating material (e.g., an acrylic resin, an epoxy resin, a phenolic resin, a polyamide resin, a polyimide resin, or other organic insulating materials). An organic insulating material forming the fourth insulating layer 240 may be variously changed according to some embodiments.

The third conductive layer may include the connection electrodes CNE of the pixels PX. For example, the third conductive layer may include the connection electrodes CNE (or bridge patterns) connected to the pixel transistors Tpx, respectively. The connection electrodes CNE may be located above the pixel transistor Tpx, respectively, and may electrically connect the pixel transistors Tpx with the light-emitting elements EL of the pixels PX together with the connection lines CNL. Each of the connection electrodes CNE may include a conductive material and may be a single-layer or multi-layer electrode.

The third conductive layer may further include at least one line including a conductive material (or a part of the at least one line), a bridge pattern, and/or a capacitor electrode. For example, the third conductive layer may include at least one power line PL (or a part of the at least one power line PL).

The fifth insulating layer 250 may include at least one inorganic film including an inorganic insulating material (e.g., the inorganic insulating materials listed above as the material for the fourth insulating layer 240 or other inorganic insulating materials) in order to provide a flat surface in the circuit layer 200. An organic insulating material forming the fifth insulating layer 250 may be variously changed according to some embodiments.

The fourth conductive layer may include the connection lines CNL including a conductive material. Optionally, the fourth conductive layer may further include at least some of the lines located in the display panel (or parts of the at least some lines) and/or a bridge pattern. The connection lines CNL may be located in an intermediate layer positioned between the layer in which the transistors T are located and the layer in which the light-emitting elements EL are located. For example, the connection lines CNL may be located in the intermediate layer located above the layer in which the transistors T are located and below the layer in which the light-emitting elements EL are located.

According to some embodiments of the present disclosure, the connection lines CNL may include, but is not limited to, a transparent conductive layer including a transparent conductive material (TCO) such as ITO and IZO. For example, the conductive material forming the connection lines CNL may be variously changed according to some embodiments.

The connection lines CNL may overlap the pixel transistors Tpx of the pixels PX and/or the connection electrodes CNE connected to the pixel transistors Tpx, respectively, and may be connected to the pixel transistors Tpx and/or the connection electrodes CNE, respectively. For example, one end of each of the connection lines CNL may be located on the connection electrode CNE of the respective pixel PX, and may be electrically connected to the connection electrode CNE of the respective pixel PX through a first contact hole CH1 in the first connection portion CP1 of the respective pixel PX.

Each first connection portion CP1 may be formed at a position in line with the respective connection electrode CNE. For example, each first connection portion CP1 may be formed at a position overlapping the respective connection electrode CNE. A part of the connection electrode CNE located at the first connection portion CP1 and/or a part of the connection line CNL may form the first contact pad located on the first connection portion CP1.

In addition, the connection lines CNL may overlap the light-emitting elements EL of the pixels PX and/or electrodes connected to the light-emitting elements EL, respectively, and may be connected to the light-emitting elements EL. For example, the other end of each of the connection lines CNL may be located under the first electrode ET1 of the light-emitting element EL of the respective pixel PX, and may be electrically connected to the light-emitting element EL of the respective pixel PX through a second contact hole CH2 in the second connection portion CP2 of the respective pixel PX.

Each second connection portion CP2 may be formed at a position in line with the respective light-emitting element EL. For example, each second connection portion CP2 may be formed at a position overlapping the first electrode ET1 included in the light-emitting element EL of the respective pixel PX. A part of the connection line CNL and/or a part of the first electrode ET1 of the light-emitting element EL located at the second connection portion CP2 may form a second contact pad located on the second connection portion CP2.

For example, the connection line of the first pixel PX1 (hereinafter referred to as a first pixel connection line CNL_P1 may connect the first pixel transistor Tpx1 located in the pixel driving unit PDU of the first pixel PX1 with the first light-emitting element EL1 located in the emission unit EMU of the first pixel PX1. According to some embodiments of the present disclosure, the first pixel connection line CNL_P1 may be regarded as an element included in the first pixel PX1.

The connection line of the second pixel PX2 (hereinafter referred to as a second pixel connection line CNL_P2 may connect the second pixel transistor Tpx2 located in the pixel driving unit PDU of the second pixel PX1 with the second light-emitting element EL2 located in the emission unit EMU of the second pixel PX2. According to some embodiments of the present disclosure, the second pixel connection line CNL_P2 may be regarded as an element included in the second pixel PX2.

The connection line of the third pixel PX3 (hereinafter referred to as a third pixel connection line CNL_P3 may connect the third pixel transistor Tpx3 located in the pixel driving unit PDU of the third pixel PX3 with the third light-emitting element EL3 located in the emission unit EMU of the third pixel PX3. According to some embodiments of the present disclosure, the third pixel connection line CNL_P3 may be regarded as an element included in the third pixel PX3.

Each of the connection lines CNL may have a length equal to the distance between the pixel driving unit PDU and the emission unit EMU of the respective pixel PX. For example, if the pixel driving unit PDU and the emission unit EMU of the first pixel PX1 are spaced apart from each other by a larger distance than the pixel driving unit PDU and the emission unit EMU of the second pixel PX2, the first pixel connection line CNL_P1 may have a larger length than the second pixel connection line CNL_P2. Similarly, if the pixel driving unit PDU and the emission unit EMU of the second pixel PX2 are spaced apart from each other by a larger distance than the pixel driving unit PDU and the emission unit EMU of the third pixel PX3, the second pixel connection line CNL_P2 may have a larger length than the third pixel connection line CNL_P3.

The connection lines CNL of the pixels PX may be located on the pixel transistors Tpx of the pixels PX and/or the connection electrodes CNE connected to the pixel transistors Tpx, respectively, and may be connected to the pixel transistors Tpx and/or the connection electrodes CNE, respectively.

The sixth insulating layer 260 may include at least one inorganic film including an inorganic insulating material (e.g., the inorganic insulating materials listed above as the material for the fourth insulating layer 240 or other inorganic insulating materials) in order to provide a flat surface in the circuit layer 200. An organic insulating material forming the sixth insulating layer 260 may be variously changed according to some embodiments.

The light-emitting element layer 300 may be located on the sixth insulating layer 260. The light-emitting element layer 300 may include light-emitting elements EL located in the emission areas EA of the pixels PX. For example, the light-emitting element layer 300 may include a first light-emitting element EL1 located in the emission area EA (e.g., the first emission area EA1) of the first pixel PX1, a second light-emitting element EL2 located in the emission area EA (e.g., the second emission area EA2) of the second pixel PX2, and a third light-emitting element EL3 located in the emission area EA (e.g., the third emission area EA3) of the third pixel PX3. The light-emitting element layer 300 may further include a pixel-defining film 310 defining the emission areas EA.

Each of the light-emitting elements EL may include a first electrode ET1 (e.g., an anode electrode) connected to the respective pixel transistor Tpx through the respective connection line CNL, and an emissive layer EML and a second electrode ET2 (e.g., a cathode electrode) sequentially arranged on the first electrode ET1. According to some embodiments of the present disclosure, each of the light-emitting elements EL may further include a first intermediate layer (e.g., a hole layer including a hole transport layer) interposed between the first electrode ET1 and the emissive layer EML, and a second intermediate layer (e.g., an electron transport layer including an electron transport layer) interposed between the emissive layer EML and the second electrode ET2.

The first electrode ET1 of each of the light-emitting element EL may include a conductive material and may be located on the circuit layer 200. For example, the first electrode ET1 may be located on the sixth insulating layer 260 in each of the emission areas EA. According to some embodiments of the present disclosure, the first electrode ET1 may include a metal material having high reflectivity. For example, the first electrode ET1 may have a single-layer structure of molybdenum (Mo), titanium (Ti), copper (Cu) or aluminum (Al), or may have a multi-layer structure including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au) or nickel (Ni), etc. (For example, ITO/Mg, ITO/MgF, ITO/Ag, ITO/Ag/ITO, etc.).

The emissive layer EML of each of the light-emitting elements EL may include a high-molecular substance or a low-molecular substance. Light emitted from the emissive layer EML may contribute to displaying images. According to some embodiments of the present disclosure, the emissive layer EML may be located in each of the pixels PX, and the emissive layer EML of each of the pixels PX may emit visible light of a color associated with the respective pixel PX. According to some embodiments, the emissive layer EML may be a common layer shared by the pixels PX of different colors, and wavelength conversion layers and/or color filters corresponding to the colors (or wavelength bands) of lights to be emitted from the pixels PX may be located in the emission areas EA of at least some of the pixels PX.

The second electrode ET2 of each of the light-emitting elements EL may include a conductive material and may be connected to the second supply voltage line VSL. According to some embodiments of the present disclosure, the second electrode ET2 may be a common layer formed over the entire display area DA to cover the emissive layer EML and the pixel-defining film 310. According to some embodiments of the present disclosure, the second electrode ET2 may be formed of a transparent conductive material (TCO) such as ITO and IZO capable of transmitting light (e.g., a transparent metal material), or a semi-transmissive conductive material (e.g., a semi-transmissive metal material) such as magnesium (Mg), silver (Ag) or an alloy of magnesium (Mg) and silver (Ag). When the second electrode ET2 is made of a semi-transmissive conductive material, the emission efficiency can be improved by a microcavity effect.

The pixel-defining film 310 may have openings associated with the emission areas EA and may surround the emission areas EA. For example, the pixel-defining film 310 may be formed to cover edges of the first electrode ET1 of each of the light-emitting elements EL, and may include an opening exposing the rest portion of the first electrode ET1 of each of the light-emitting elements EL. The area where the exposed first electrode ET1 and the emissive layer EML overlap each other (or an area including the same) may be defined as the emission area EA of each pixel PX.

The pixel-defining film 310 may include at least one organic film including an organic insulating material. According to some embodiments of the present disclosure, the pixel-defining film 310 may include an organic insulating material such as polyacrylate resin, epoxy resin, phenolic resin, polyamide resin, polyimide resin, unsaturated polyesters resin, poly phenylen ether resin, poly phenylene sulfide resin, and benzocyclobutene (BCB). An organic insulating material forming the pixel-defining film 310 is not particularly limited, and may vary depending on different embodiments.

At least some of the pixels PX located in the display area DA may include pixel transistors Tpx located in the first display area DA1 and light-emitting elements EL located in the second display area DA2. For example, the first pixel PX1 shown in FIG. 6 may include a first pixel transistor Tpx1 located in the first display area DA1 and a first light-emitting element EL1 located in the second display area DA2. In this instance, a first pixel connection line CNL_P1 may be extended from a first connection portion CP1 of the first pixel PX1 located in the first display area DA1 to a second connection portion CP2 of the first pixel PX1 located in the second display area DA2. At least some of the pixels PX including the light-emitting elements EL located in the second display area DA2 may overlap the embedded driver circuit SDR located in the second display area DA2. For example, the first light-emitting element EL1 of the first pixel PX1 may overlap at least one driver transistor Tsd.

Other pixels PX among the pixels PX located in the display area DA may include pixel transistors Tpx located in the first display area DA1 and light-emitting elements EL located in the first display area DA1. For example, the second pixel PX2 shown in FIG. 6 may include a second pixel transistor Tpx2 located in the first display area DA1 and a second light-emitting element EL2 located in the first display area DA1, and the third pixel PX3 may include a third pixel transistor Tpx3 located in the first display area DA1 and a third light-emitting element EL3 located in the first display area DA1. In this instance, the second pixel connection line CNL_P2 may be extended from a first connection portion CP1 to a second connection portion CP2 of the second pixel PX2 in the first display area DA1. The third pixel connection line CNL_P3 may be extended a first connection portion CP1 to a second connection portion CP2 of the third pixel PX3 in the first display area DA1.

According to some embodiments of the present disclosure, in a pixel PX including a pixel transistor Tpx located in the first display area DA1 and a light-emitting element EL located in the second display area DA2 (e.g., the first pixel PX1) the pixel driving unit PDU and the light-emitting element EL may be spaced apart from each other by a greater distance than those in a pixel PX (e.g., the second pixel PX2 or the third pixel PX3) including the pixel transistor Tpx and the light-emitting element EL located in the first display area DA1. In this instance, a connection line CNL of a pixel PX including a pixel transistor Tpx located in first display area DA1 and a light-emitting element EL located in second display area DA2 (e.g., the first pixel connection line CNL_P1) may have a greater distance than a connection line CNL of a pixel PX including a pixel transistor Tpx and light-emitting element EL located in first display area DA1 (e.g., the second pixel connection line CNL_P2 or the third pixel connection line CNL_P3).

The encapsulation layer 400 may be located on the light-emitting element layer 300 at least in the display area DA. The encapsulation layer 400 can block the permeation of oxygen or moisture into the light-emitting element layer 300 and can alleviate electrical or physical shock on the circuit layer 200 and the light-emitting element layer 300.

According to some embodiments of the present disclosure, the encapsulation layer 400 may include a first encapsulation layer 410, a second encapsulation layer 420, and a third encapsulation layer 430 sequentially located on the light-emitting element layer 300. The first encapsulation layer 410 and the third encapsulation layer 430 may include an inorganic insulating material, and the second encapsulation layer 420 may include an organic insulating material.

According to some embodiments of the present disclosure, an additional layer may be located on the encapsulation layer 400. For example, at least one of a sensor layer (e.g., a touch sensor layer), a polarization layer, or a protective layer may be located on the encapsulation layer 400.

The display device 10 according to the embodiments of FIGS. 1 to 6 further includes the first display area DA1 in which the pixel driving units PDU of the pixels PX are located, as well as the second display area DA2 around the first display area DA1, and thus it can include a more expanded display area DA. For example, the emission units EMU of the pixels PX may be located in the first display area DA1 and the second display area DA2. According to some embodiments, both the first display area DA1 where the pixel driving units PDU are located and the second display area DA2 where the embedded driver circuit SDR is located may be utilized as the display area DA. As a result, the non-display area NA of the display device 10 can be reduced and the display area DA can be expanded.

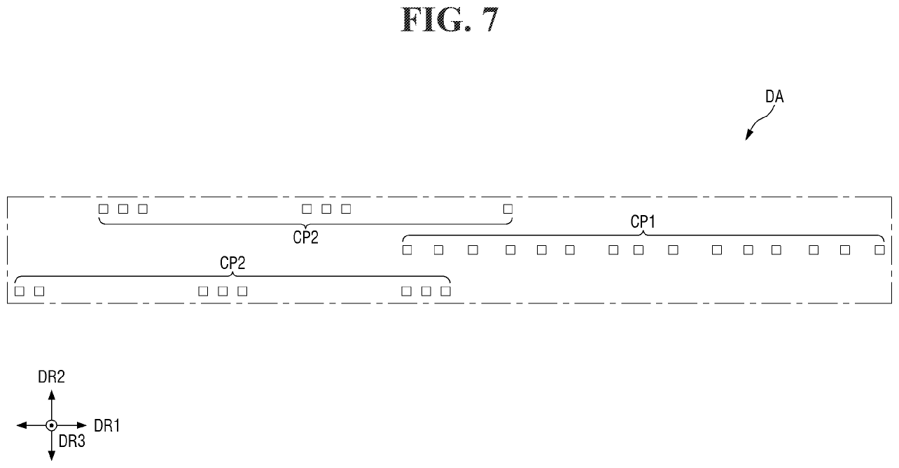

FIG. 7 is a plan view showing first connection portions CP1 and second connection portions CP2 according to some embodiments of the present disclosure. For example, FIG. 7 shows an example of the first connection portions CP1 and the second connection portions CP2 located at a portion of the display area DA.

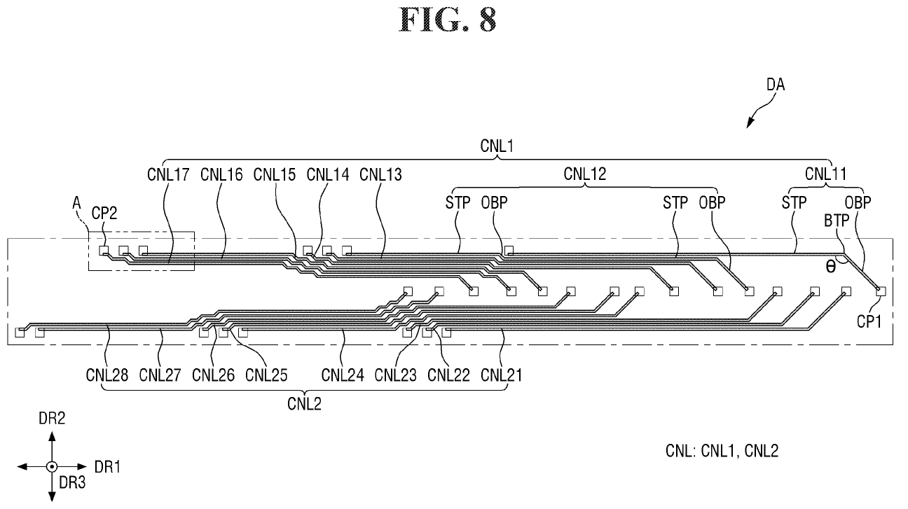

FIG. 8 is a plan view showing connection lines CNL according to some embodiments of the present disclosure. For example, FIG. 8 shows an example of the connection lines CNL that connect the first connection portions CP1 with the second connection portions CP2.

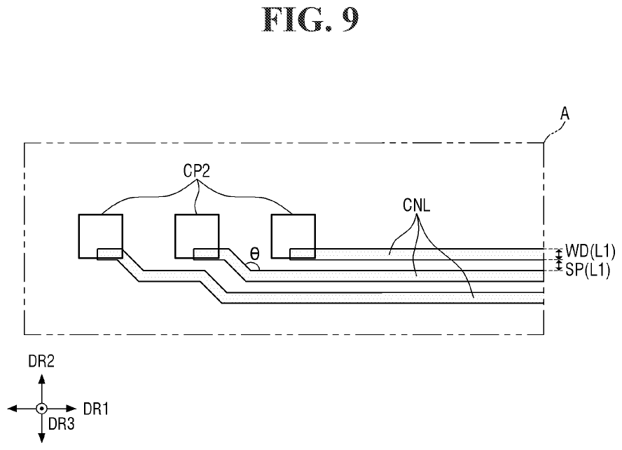

FIG. 9 is a plan view showing parts of connection lines CNL according to some embodiments of the present disclosure. For example, FIG. 9 is an enlarged, plan view showing area A of FIG. 8.

Referring to FIGS. 7 to 9 in conjunction with FIGS. 1 to 6, adjacent ones of the first connection portions CP1 located in the display area DA may be arranged in parallel in the first direction DR1. For example, the plurality of first connection portions CP1 may be sequentially and/or continuously arranged in the first direction DR1.

The plurality of second connection portions CP2 associated with the plurality of first connection portions CP1 (e.g., the plurality of second connection portions CP2 connected to the first connection portions CP1) may be at positions spaced apart from the first connection portions CP1 in at least the first direction DR1. For example, the second connection portions CP2 associated with the first connection portions CP1 may be located at positions spaced apart from the first connection portions CP1 in the first direction DR1 and the second direction DR2, respectively. For example, the second connection portions CP2 of the pixels PX may be located at positions spaced apart from the first connection portions CP1 of the pixels PX in both the first direction DR1 and the second direction DR2.

Each of the connection lines CNL may have a structure bent by an angle e equal to a multiple of 45° at at least one bent portion BTP. For example, each of the connection lines CNL may include at least one straight portion STP extended in the first direction DR1, and at least one oblique portion OBP connected to the straight portion STP and extended in an oblique direction inclined by an angle θ equal to a multiple of 45° with respect to the first direction DR1.

The connection lines CNL may be bent by the same angle 0 at bent portions BTP where the straight portions STP meet the oblique portions OBP. For example, the angles θ between the straight portions STP and the oblique portions OBP of the connection lines CNL may be all equal. According to some embodiments of the present disclosure, the angles θ between the straight portions STP and the oblique portions OBP of the connection lines CNL may be 135°, which is a multiple of 45° in the obtuse angle range.

The connection lines CNL may be patterns in which the straight portions STP and the oblique diagonal portions OBP are formed as a single piece. For example, the straight portions STP and the oblique portions OBP of each of the connection lines CNL may be formed integrally and patterned at the same time.

According to some embodiments of the present disclosure, the connection lines CNL may include a first group of connection lines CNL1 (for example, the first to seventh connection lines CNL11 to CNL17 of the first group) that connect at least some of the first connection portions CP1 arranged in parallel in the first direction DR1 with the second connection portions CP2 shifted in the same direction with respect to the first and second directions DR1 and DR2 For example, the first group of connection lines CNL1 may connect the first connection portions CP1 with the second connection portions CP2 that are located more to the left and upper sides than the first connection portions CP1 and are arranged in parallel in the first direction DR1. The first group of connection lines CNL1 may include oblique portions OBP extended in substantially the same direction.

According to some embodiments of the present disclosure, one connection line CNL of the first group of connection lines CNL1 may have a shape and/or a length corresponding to the shortest path among paths that may be extended from the first connection portion CP1 to the second connection portion CP2 of the respective pixel PX within the range in which the portions forming the connection lines CNL (e.g., the straight portion STP and the oblique portion OBP satisfy the angle conditions described above. For example, the one connection line CNL may include a single straight portion STP and a single oblique portion OBP. For example, among the first group of connection lines CNL1, the first connection line CNL11 located at the rightmost position in the first direction DR1 may have the shortest length, and may include a single straight portion STP and a single oblique portion OBP.

Among the connection lines CNL1 of the first group, each of the lines other than the first connection line CNL11 may include at least two straight portions STP and at least two oblique portions OBP. For example, among the first group of connection lines CNL1, a second connection line CNL12 adjacent to the first connection line CNL11 may include two straight portions STP and two oblique portions OBP. Each of the straight portions STP of the second connection wire CNL12 may be arranged in parallel with the straight portion STP of the first connection line CNL11 in the first direction DR1 or in the second direction DR2 orthogonal to the first direction DR1.

According to some embodiments of the present disclosure, the straight portions STP of the first group of connection lines CNL1 may be extended in the same direction and may be substantially parallel to one another. Similarly, the oblique portions OBP of the first group of connection lines CNL1 may be extended in the same direction and may be substantially parallel to one another.

According to some embodiments of the present disclosure, the connection lines CNL may further include a second group of connection lines CNL2 that are arranged in a different direction from the first group of connection lines CNL1 with respect to the first connection portions CP1 in at least one of the first or second directions DR1 or DR2. For example, the connection lines CNL may further include a second group of connection lines CNL2 (for example, the first to eighth connection lines CNL21 to CNL28 of the second group) that connect some others of the first connection portions CP1 arranged in parallel in the first direction DR1 with the second connection portions CP2 shifted in the same direction with respect to the first and second directions DR1 and DR2 For example, the second group of connection lines CNL2 may connect the first connection portions CP1 with the second connection portions CP2 that are located more to the left and lower sides than the first connection portions CP1 and are arranged in parallel in the first direction DR1. The second group of connection lines CNL1 may include oblique portions OBP extended in substantially the same direction.

According to some embodiments of the present disclosure, one connection line CNL of the second group of connection lines CNL2 may have a shape and/or a length corresponding to the shortest path among paths that may be extended from the first connection portion CP1 to the second connection portion CP2 of the respective pixel PX within the range in which the portions forming the connection lines CNL (e.g., the straight portion STP and the oblique portion OBP satisfy the angular condition described above. For example, the one connection line CNL may include a single straight portion STP and a single oblique portion OBP. For example, among the second group of connection lines CNL2, the first connection line CNL21 located at the rightmost position in the first direction DR1 may have the shortest length, and may include a single straight portion STP and a single oblique portion OBP. Among the connection lines CNL2 of the second group, each of the lines other than the first connection line CNL21 may include at least two straight portions STP and at least two oblique portions OBP. For example, among the second group of connection lines CNL2, a second connection line CNL22 adjacent to the first connection line CNL21 may include two straight portions STP and two oblique portions OBP. Each of the straight portions STP of the second connection wire CNL22 may be arranged in parallel with the straight portion STP of the first connection line CNL21 in the first direction DR1 or in the second direction DR2.

According to some embodiments of the present disclosure, the straight portions STP of the second group of connection lines CNL1 may be extended in the same direction and may be substantially parallel to one another. Similarly, the oblique portions OBP of the second group of connection lines CNL2 may be extended in the same direction and may be substantially parallel to one another.

According to some embodiments of the present disclosure, the connection lines CNL may have substantially the same width WD. As used herein, the phrase that the connection lines CNL have substantially the same width WD may mean that each of the connection lines CNL has a width WD of a particular length (e.g., the first length L1) or has a width WD within a range that can be determined to be substantially equal to the particular length with a tolerance range (e.g., a set or predetermined tolerance range).

According to some embodiments of the present disclosure, a group of connection lines CNL adjacent to each other (e.g., the connection lines CNL1 of the first group or the connection lines CNL2 of the second group) may be arranged at a substantially uniform spacing SP. As used herein, the phrase that the connection lines CNL have substantially the same spacing SP may mean that the connection lines CNL may be uniformly arranged sequentially and/or continuously with a spacing SP of a particular length or a spacing SP that can be determined to be substantially equal to the particular length within a tolerance range (e.g., a set or predetermined tolerance range).

According to some embodiments of the present disclosure, a group of connection lines CNL adjacent to each other may be arranged sequentially and/or continuously with a spacing SP of the same length (e.g., the spacing SP of the first length L1) that is substantially equal to the width WD of each of the connection lines CNL. For example, the connection lines CNL1 of the first group, e.g., the first to seventh connection lines CNL11 to CNL17 of the first group may be arranged sequentially and/or continuously such that they are spaced apart from each other by the spacing SP of the first length L1 equal to the width WD of each of the connection lines CNL at at least straight portions STP. For example, if each of the connection lines CNL has a width WD of approximately 3 μm, the first group of connection lines CNL1 or the second group of connection lines CNL2 may be arranged sequentially and/or continuously such that they are spaced apart from each other by a spacing SP of approximately 3 μm at at least straight portions STP.

According to the above-described embodiments, the connection lines CNL may be arranged in the display area DA at a regular spacing. In addition, the connection lines CNL may be formed to have a smaller length (e.g., the shortest length corresponding to the shortest path among paths that can reach the second connection portion CP2 from the first connection portion CP1 while the straight portion STP and the oblique portion OBP are extended in a direction and/or at an angle) while maintaining a uniform spacing and not meeting each other.

In this manner, the connection lines CNL can be more uniformly formed with the target width WD, and the resistance of each of the connection lines CNL and the resistance deviations of the connection lines CNL can be reduced or minimized. For example, as the connection lines CNL are arranged at the generally uniform spacing, process errors and/or process deviations that may occur due to differences in exposure conditions in a patterning process (e.g., a patterning process including a photolithography process) for forming the connection lines CNL can be prevented or reduced, and the connection lines CNL can be formed with a more uniform width WD. In addition, by forming the connection lines CNL to the optimized length (e.g., a shorter length), it is possible to reduce or minimize the resistance of each of the connection lines CNL.

Therefore, according to the above-described embodiments, the pixels PX can emit light with more uniform luminance in response to the respective data signals. Accordingly, the image quality of the display device 10 can be improved.

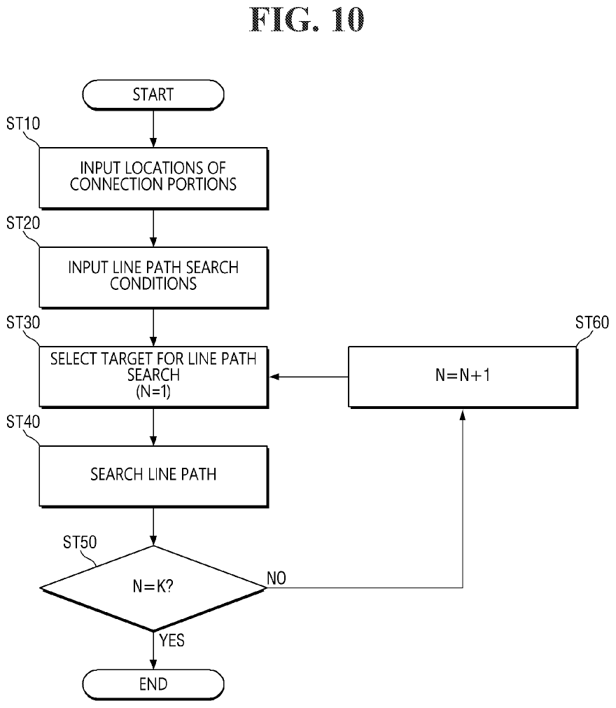

FIG. 10 is a flowchart illustrating a method of forming connection lines CNL according to some embodiments of the present disclosure. For example, FIG. 10 schematically illustrates a method of designing the connection lines CNL, which includes searching for the optimal line path of each of the connection lines CNL.

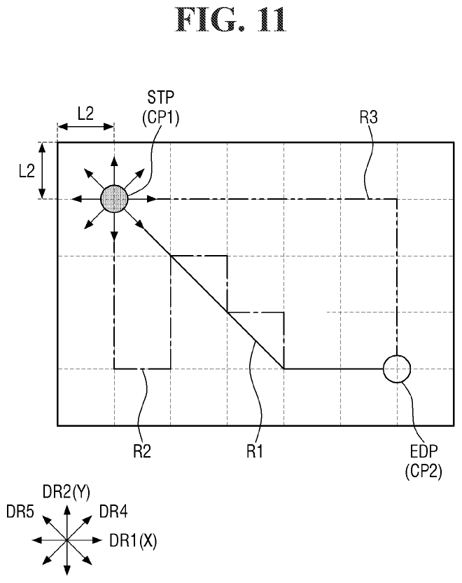

FIG. 11 is a plan view showing found line paths according to some embodiments of the present disclosure. For example, FIG. 11 shows an example of line paths that meet specified line path search conditions.

Referring to FIGS. 10 and 11 in conjunction with FIGS. 1 to 9, the display device 10 may include pixels PX that include the pixel transistors Tpx, the light-emitting elements EL and connection lines CNL connecting the pixel transistors Tpx with the light-emitting elements EL, respectively. The method of fabricating the display device 10 may include: sequentially searching for optimal line paths for the connection lines CNL according to the following steps; and forming the connection lines CNL according to the found line paths. For example, setting the line paths including the following steps may be performed in the step of designing the connection lines CNL of the pixels PX prior to the process of forming the pixels PX. The connection lines CNL formed along the line paths set or designed by the following steps may be formed as patterns with locations, shapes and/or lengths that meet the path search conditions set or specified in the following designing step:

### ST10: Input Locations of Connection Portions

Initially, in order to set the line paths for forming the connection lines CNL (for example, a movement path or a connection path from a first connection portion CP1 to a second connection portion CP2 corresponding to each of the connection lines CNL), the locations of the respective connection portions to be connected to the respective connection lines CNL may be input into a design program. For example, based on a graphic design system (GDS), the coordinates of start points STP associated with the first connection portions CP1 (e.g., the first connection portions CP1 connected to the pixel transistors Tpx) and the coordinates of end points EDP associated with the second connection portions CP2 (for example, the second connection portions CP2 connected to the light-emitting elements EL) may be input.

### ST20: Input Line Path Search Conditions

Subsequently, desired line path search conditions may be input for the connection lines CNL. For example, as shown in FIG. 11, the minimum movement unit applied to a process of searching for line paths for the connection lines CNL may be set as a grid of squares having four sides of a second length L2 equal to a multiple (e.g., twice) of the width WD of each of the connection lines CNL. For example, when each of the connection lines CNL has the width WD of the first length L1, the minimum movement unit of line movement applied in a process of searching for the paths for the connection lines CNL may be set as a grid of squares having four sides of the second length L2 equal to twice the first length L1. Each of the connection lines CNL thus formed may have the width WD of the first length L1, and adjacent connection lines CNL may be uniformly arranged at a spacing SP of the first length L1.

In addition, the movement direction from one point to the next point on the movement path applied in the process of searching for the line paths for the connection lines CNL may be restricted to only in the first direction DR1 (for example, the X direction) and the second direction DR2 (for example, the Y direction) in which the sides of the squares are extended, and diagonal directions of the grid (for example, a fourth direction DR4 and a fifth direction DR5). For example, at a point where the line path of each connection line CNL starts or bends, it may move only in the X or Y direction to reach the next point, or it may move to a point located in a diagonal direction separated by the same distance in the X and Y directions. Each of the connection lines CNL thus formed may include at least one straight portion STP, and at least one oblique portion OBP extended in an oblique direction inclined by an angle θ equal to a multiple of 45° with respect to the first direction DR1 in which the straight portion STP is extended.

Additionally, when the connection lines CNL are located in the same layer, in sequentially searching for the line paths for the connection lines CNL, a path for at least one connection line CNL that has been found first may be designated as an obstacle to avoid in searching for a line path for a subsequent connection line CNL. In this manner, it is possible to search for the line path for the target connection line CNL by avoiding the path of the at least one connection line CNL, and thus it is possible to set the paths of the connection lines CNL so that the connection lines CNL do not meet each other.

### ST30 to ST60: Sequential Search for Line Paths

Subsequently, under the set line path search conditions, the line paths for the connection lines CNL may be sequentially searched for. For example, Priorities are assigned to the start points STP associated with the first connection portions CP1 based on a particular direction and/or position, and the optimal line path can be searched for from among the line paths from the target start point STP to the corresponding end point EDP (e.g., the end point EDP associated with the second connection portion CP2 to be connected to the selected first connection portion CP1) based on a depth first search (DFS) algorithm. For example, sequences numbers are assigned to the start points STP, respectively. The start point STP assigned No. 1 (N=1) and the corresponding end point EDP are selected as the target for the line path search. Then, the optimal line path from the selected start point STP to the end point EDP may be searched for. Subsequently, the optimal line path may be searched for the start point STP corresponding to the next sequence number (e.g., No. 2) to the corresponding end point EDP, and so on by increasing the sequence number one by one. In this manner, the optimal line paths may be sequentially searched for the start points STP assigned No. 1 to the last number to the corresponding end points EDP.

According to some embodiments of the present disclosure, search conditions for the optimal line path may be the shortest distance. For example, as shown in FIG. 11, among the line paths that can reach the end point EDP from the start point STP, which is the target of the line path search, a first line path R1, a second line path R2 and a third line path R3 may be found under the line path search conditions (e.g., the set or predetermined or designated line path search conditions). In this instance, among the found first line path R1, second line path R2 and third line path R3, the line path having the shortest distance, e.g., the first line path R1 may be selected as the optimal line path, and accordingly the line path search for the target point (e.g., the start point STP and end point EDP of the sequence number) may be completed. For example, within the range that satisfies the previously input line path search conditions, the line paths that can reach the end points EDP from the designated start points STP (e.g., the first line path R1, the second line path R2 and the third line path R3) may be received as rewards, and the path of the shortest distance (for example, the first line path R1) may be found as the optimal line path for the target point.

According to some embodiments of the present disclosure, each of the line paths may be output in the form of coordinates corresponding to paths through which the connection lines CNL pass, and the positions and pattern shapes of the connection lines CNL corresponding to the line paths may be derived based on the GDS. For example, as described above with reference to FIGS. 10 and 11, the line paths for the connection lines CNL for connecting the first connection portions CP1 with the second connection portions CP2 of FIG. 7 may be sequentially searched for. Accordingly, it is possible to design the connection lines CNL having the locations and shapes shown in FIG. 8.

Once the design of the connection lines CNL is completed, the connection lines CNL may be formed between the first connection portions CP1 and the second connection portions CP2 via a process of fabricating a display panel including a pixel forming process.

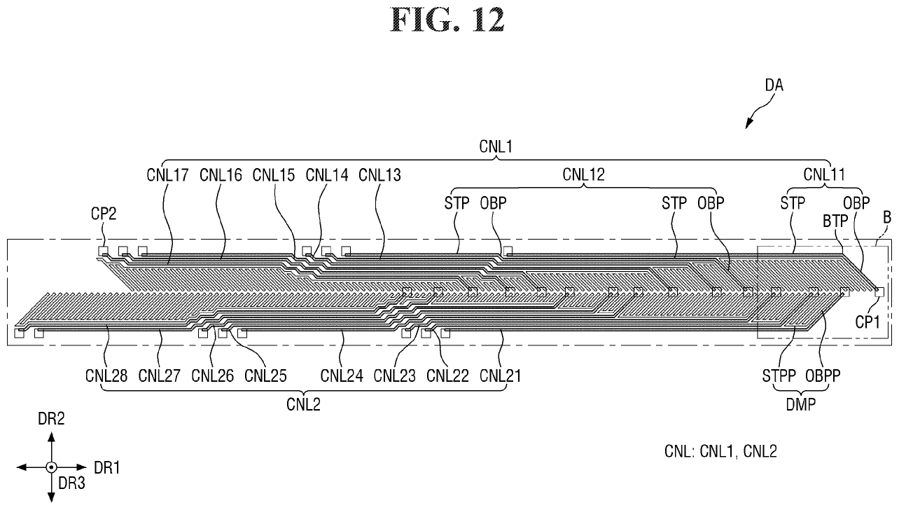

FIG. 12 is a plan view showing connection lines CNL and dummy patterns DMP according to some embodiments of the present disclosure. For example, FIG. 12 is a plan view showing an example of the connection lines CNL of FIG. 8 and dummy patterns DMP positioned between the connection lines CNL.

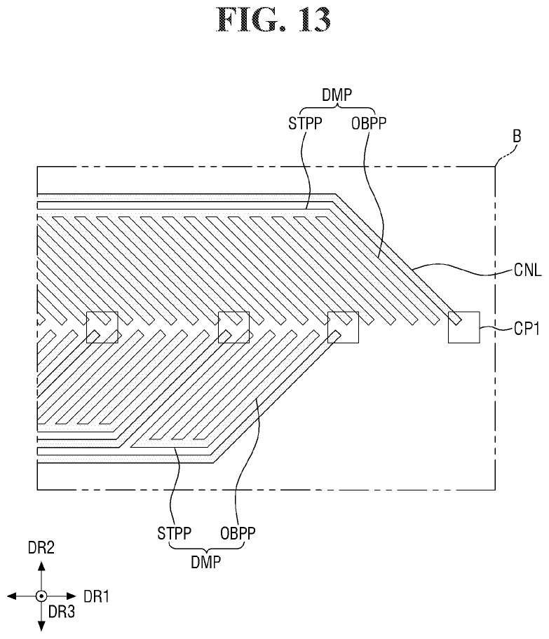

FIG. 13 is a plan view partially showing connection lines CNL and dummy patterns DMP according to some embodiments of the present disclosure. For example, FIG. 13 is an enlarged plan view showing area B of FIG. 12.

Referring to FIGS. 12 and 13 in conjunction with FIGS. 1 to 11, the display device 10 may further include dummy patterns DMP located in spaces between the connection lines CNL. According to some embodiments of the present disclosure, the dummy patterns DMP may have shapes conforming to the connection lines CNL. For example, the dummy patterns DMP may include at least one straight pattern STPP parallel to the straight portions STP of the connection lines CNL, and at least one oblique pattern OBPP parallel to the oblique portions OBP of the connection lines CNL.

The connection lines CNL and the dummy patterns DMP may be arranged at a generally uniform spacing in the display area DA including the first display area DA1 and the second display area DA2. For example, the dummy patterns DMP may have substantially the same width as the connection lines CNL and may be arranged at substantially the same spacing as the connection lines CNL.

The dummy patterns DMP may be formed together with the connection lines CNL. For example, in the process of forming the connection lines CNL, the dummy patterns DMP may be formed on the same layer as the connection lines CNL using the same material as the connection lines CNL.

According to some embodiments of the present disclosure, the dummy patterns DMP may be formed only at some portions of the display area DA. For example, the dummy patterns DMP may be arranged only around each group of connection lines CNL (e.g., the first group of connection lines CNL1 and the second group of connection lines CNL2). It should be understood, however, that embodiments according to the present disclosure are not limited thereto. For example, the connection lines CNL and the dummy patterns DMP may be generally uniformly formed in the display area DA. Each dummy pattern DMP may or may not overlap with the first connection portion CP1 and/or the second connection portion CP2 located around it. Even if at least one dummy pattern DMP overlaps with the first connection portion CP1 and/or the second connection portion CP2 located around it, the at least one dummy pattern DMP may not be electrically connected to the first connection portion CP1 and/or the second connection portion CP2.

According to some embodiments of the present disclosure, the dummy patterns DMP may be formed at positions spaced apart from the nearby signal lines by a distance (e.g., a set or predetermined distance) in consideration of noise that may occur between the nearby signal lines (e.g., the scan lines SL and/or the data lines DL) and the dummy patterns DMP. According to some embodiments of the present disclosure, the dummy patterns DMP may be connected to the power lines PL. For example, the dummy patterns DMP may be connected to one of: a first supply voltage line VDL, a second supply voltage line VSL, a first initialization voltage line VIL1 and a second initialization voltage line VIL2.

According to the above-described embodiments, the connection lines CNL and the dummy patterns DMP may be arranged at a uniform spacing in the display area DA. Accordingly, it is possible to prevent or reduce process errors and/or process deviations of the connection lines CNL, and the connection lines CNL can be more uniformly formed.

As described above, the display device 10 according to some embodiments may include the emission units EMU of the pixels PX located in the first display area DA1 in which the pixel driving units PDU of the pixels PX are located and the second display area DA2 around the first display area DA1 (e.g., the area where the embedded driver circuit SDR is located). As a result, the non-display area NA of the display device 10 can be reduced and the display area DA can be expanded.

In addition, the display device 10 according to some embodiments may include connection lines CNL each connecting the pixel driving unit PDU with the emission unit EMU of the respective pixels PX. The connection lines CNL may have a shape that can be formed at a uniform spacing and/or width, may be located or arranged in the display area DA at a uniform spacing, and may have the optimized length (e.g., a shorter length). As a result, the connection lines CNL can be more uniformly formed, and voltage drop and/or voltage drop deviations in the connection lines CNL can be reduced or suppressed.

In concluding the detailed description, those skilled in the art will appreciate that many variations and modifications can be made to the embodiments without substantially departing from the spirit and scope of embodiments according to the present invention. Therefore, the disclosed embodiments of the invention are used in a generic and descriptive sense only and not for purposes of limitation.

What is claimed is:

1. A display device comprising:
a substrate comprising a first display area and a second display area around the first display area;
pixels on the substrate and comprising respective pixel transistors in the first display area, and respective light-emitting elements in the first display area and the second display area and connected to the respective pixel transistors; and
connection lines connecting the pixel transistors with the light-emitting elements, respectively,
wherein each of the connection lines comprises one or more straight portions extending in a first direction, and one or more oblique portions connected to the straight portions and extending in an oblique direction inclined by an angle equal to a multiple of 45° with respect to the first direction, and
wherein angles formed by the straight portions and the oblique portions of the connection lines are equal to each other.

2. The display device of claim 1, wherein the angles formed by the straight portion and the oblique portion of each of the connection lines is equal to 135°.

3. The display device of claim 1, wherein each of the connection lines has a width of a first length.

4. The display device of claim 3, wherein straight portions of two adjacent ones of the connection lines are spaced apart from each other by a spacing equal to the first length.

5. The display device of claim 1, wherein the pixels further comprise:
connection electrodes connected to the respective pixel transistors;
first connection portions overlapping the connection electrodes; and
second connection portions overlapping first electrodes of the light-emitting elements, and
wherein each of the connection lines is connected between a first connection portion and a second connection portion of one of the pixels.

6. The display device of claim 5, wherein the connection lines comprise:
a first connection line comprising a single straight portion and a single oblique portion; and
a second connection line adjacent to the first connection line and comprising at least two straight portions and at least two oblique portions.

7. The display device of claim 6, wherein the first connection portion connected to the first connection line and the first connection portion connected to the second connection line are arranged in parallel in the first direction, and
wherein the second connection portion connected to the first connection line and the second connection portion connected to the second connection line are arranged in parallel in the first direction.

8. The display device of claim 7, wherein each of the straight portions of the second connection line is parallel to the straight portion of the first connection line in the first direction or in a second direction orthogonal to the first direction.

9. The display device of claim 1, further comprising:
a dummy pattern in a space between the connection lines and comprising a straight pattern parallel to the straight portions of the connection lines and an oblique pattern parallel to the oblique portions of the connection lines.

10. The display device of claim 9, wherein the connection lines and the dummy pattern are arranged at a uniform spacing in a display area including the first display area and the second display area.

11. The display device of claim 9, wherein the dummy pattern is in a same layer and comprises a same material as the connection lines.

12. The display device of claim 1, further comprising:
a circuit layer on the substrate and comprising the pixel transistors; and
a light-emitting element layer overlapping the circuit layer and comprising the light-emitting elements.

13. The display device of claim 12, further comprising:
an embedded driver circuit in the circuit layer and comprising a driver transistor in the second display area.

14. The display device of claim 13, wherein the embedded driver circuit overlaps the light-emitting element of at least one of the pixels.

15. The display device of claim 13, wherein a first pixel among the pixels comprises a first pixel transistor in the first display area and a first light-emitting element in the second display area, and
wherein a second pixel among the pixels comprises a second pixel transistor in the first display area and a second light-emitting element in the first display area.

16. The display device of claim 15, wherein a connection line connecting the first pixel transistor with the first light-emitting element has a greater length than a connection line connecting the second pixel transistor with the second light-emitting element.

17. The display device of claim 1, wherein each of the pixels comprises a pixel driving unit comprising at least one pixel transistor and an emission unit comprising at least one light-emitting element, and
wherein, among the pixels, at least two pixels having respective pixel driving units adjacent to each other and respective light-emitting units adjacent to each other form a unit pixel.

18. The display device of claim 17, wherein pixel driving units and light-emitting units of unit pixels formed by the pixels are in the first display area and the second display area,
wherein the pixel driving units of the unit pixels are in the first display area at a first pitch in the first direction, and
wherein the emission units of the unit pixels are in the first display area and the second display area at a second pitch greater than the first pitch in the first direction.

19. The display device of claim 1, wherein the straight portion and the oblique portion of each of the connection lines are formed as a single piece.

20. A method of fabricating a display device comprising pixels, wherein the pixels comprise pixel transistors, light-emitting elements and connection lines connecting the pixel transistors with the light-emitting elements, the method comprising:
inputting locations of first connection portions connected to the pixel transistors and locations of second connection portions connected to the light-emitting elements into a design program;
inputting line path search conditions for the connection lines;
sequentially searching for line paths for the connection lines under the line path search conditions; and
forming the connection lines between the first connection portions and the second connection portions according to the line paths that are found,
wherein the line path search conditions comprise a condition that each square in a grid of squares having four sides with a length equal to a multiple of a width of each of the connection lines is a minimum movement unit, and a condition that a path moves only in straight line directions in which the sides of the grid extend and in diagonal directions of the grid.
